(19) United States
(12) Patent Application Publication
(10) Pub. No.: US 2026/0261242 A1
(43) Pub. Date: Sep. 3, 2026

(54) COMPARATOR WITH PHASE REVERSAL PREVENTION AND REDUCED TRANSISTOR STRESS

(71) Applicant: TEXAS INSTRUMENTS INCORPORATED, Dallas, TX (US)

(72) Inventors: Ho-Young Lee, San Jose, CA (US); Satoshi Sakurai, San Carlos, CA (US)

(21) Appl. No.: 19/066,285

(22) Filed: Feb. 28, 2025

(51) Int. Cl. H03F 1/02; H03F 3/45

(52) U.S. Cl. CPC H03F 1/0205; H03F 3/45179; H03F 2203/45028

(57) ABSTRACT

An apparatus includes an amplifier having first and second inputs and an output. A hysteresis control circuit has a first input coupled to the first input of the amplifier, a second input coupled to the second input of the amplifier, and first and second outputs coupled to the amplifier. The hysteresis control circuit is configured to be disabled in response to a common mode voltage at the first and second inputs of the amplifier being above a threshold and to be enabled in response to the common mode voltage being below the threshold. When enabled, the hysteresis control circuit is configured to change an output voltage of the amplifier.

### BACKGROUND

A comparator produces a digital output signal based on whether one input signal to the comparator is greater than or less than another input signal.

### SUMMARY

In one example, an apparatus includes a first amplifier having first and second inputs and first and second outputs. A first transistor has first and second terminals, the first terminal coupled to a third terminal of the first amplifier. A second transistor has fourth and fifth terminals. The fourth terminal coupled to a sixth terminal of the first amplifier, and the fifth and second terminals coupled together. A current source circuit has a first input coupled to the first input of the first amplifier, a second input coupled to the second input of the first amplifier and has a current source circuit terminal coupled to the second and fifth terminals. A second amplifier has a first input coupled to the first output of the first amplifier, a second input coupled to the second output of the first amplifier, and first and second outputs. The second amplifier includes a third transistor having a first control terminal coupled to the first output of the first amplifier, a fourth transistor having a second control terminal coupled to the second output of the first amplifier, and a diode device coupled between the third and fourth transistor. A Schmitt trigger has a first input coupled to the first output of the second amplifier and a second input coupled to the second output of the second amplifier.

In another example, an apparatus includes a first amplifier having first and second inputs and first and second outputs. A second amplifier has a first input coupled to the first output of the first amplifier, a second input coupled to the second output of the first amplifier, and first and second outputs. The second amplifier includes a first transistor having a first control terminal coupled to the first output of the first amplifier, a second transistor having a second control terminal coupled to the second output of the first amplifier, and a diode device coupled between the first and second transistor. A Schmitt trigger has a first input coupled to the first output of the second amplifier, a second input coupled to the second output of the second amplifier, and an output. A voltage detection circuit has a first input coupled to the first input of the first amplifier, a second input coupled to the second input of the second amplifier, and an output. The voltage detection circuit is configured to generate a signal at the output of the voltage detection circuit based on whether a common mode voltage at the first and second inputs of the first amplifier is below or above a threshold. A latch is coupled to the output of the Schmitt trigger and to the output of the voltage detection circuit. The latch is configured to latch the output of the Schmitt trigger in response to the signal from the voltage detection circuit indicating that the common mode voltage is below the threshold.

In yet another example, an apparatus includes an amplifier having first and second inputs and an output. A hysteresis control circuit has a first input coupled to the first input of the amplifier, a second input coupled to the second input of the amplifier, and first and second outputs coupled to the amplifier. The hysteresis control circuit is configured to be disabled in response to a common mode voltage at the first and second inputs of the amplifier being above a threshold and to be enabled in response to the common mode voltage being below the threshold. When enabled, the hysteresis control circuit is configured to change an output voltage of the amplifier.

In another example, an apparatus includes a first amplifier having first and second inputs and first and second outputs. A second amplifier has a first input coupled to the first output of the first amplifier, a second input coupled to the second output of the first amplifier, and first and second outputs. The second amplifier includes a first transistor having a first control terminal coupled to the first output of the first amplifier, a second transistor having a second control terminal coupled to the second output of the first amplifier, and a diode device coupled between the first and second transistor. A Schmitt trigger has a first input coupled to the first output of the second amplifier and a second input coupled to the second output of the second amplifier

### BRIEF DESCRIPTION OF THE DRAWINGS

FIG. 1 is a schematic diagram of a comparator, in an example.

FIG. 2 is a schematic diagram of a comparator including a hysteresis control circuit, in another example.

FIG. 3 is a schematic diagram of a current source circuit included within the hysteresis control circuit, in an example.

FIG. 4 are waveforms illustrating the operation of the comparator and current source circuit of FIGS. 2 and 3.

FIG. 5 is a schematic diagram of a comparator including a voltage detection circuit and an output latch, in another example.

FIG. 6 is a schematic diagram of a comparator including a class AB amplifier having a diode device to reduce hot carrier injection stress in the class AB amplifier, in another example.

FIG. 7 are waveforms illustrating the operation of the comparator of FIG. 6, in an example.

FIG. 8 is a schematic diagram of a comparator including the hysteresis control circuit and diode device, in another example.

FIG. 9 is a schematic diagram of a comparator including the hysteresis control circuit and voltage detection circuit, in another example.

### DETAILED DESCRIPTION

The same reference numbers or other reference designators are used in the drawings to designate the same or similar (either by function and/or structure) features.

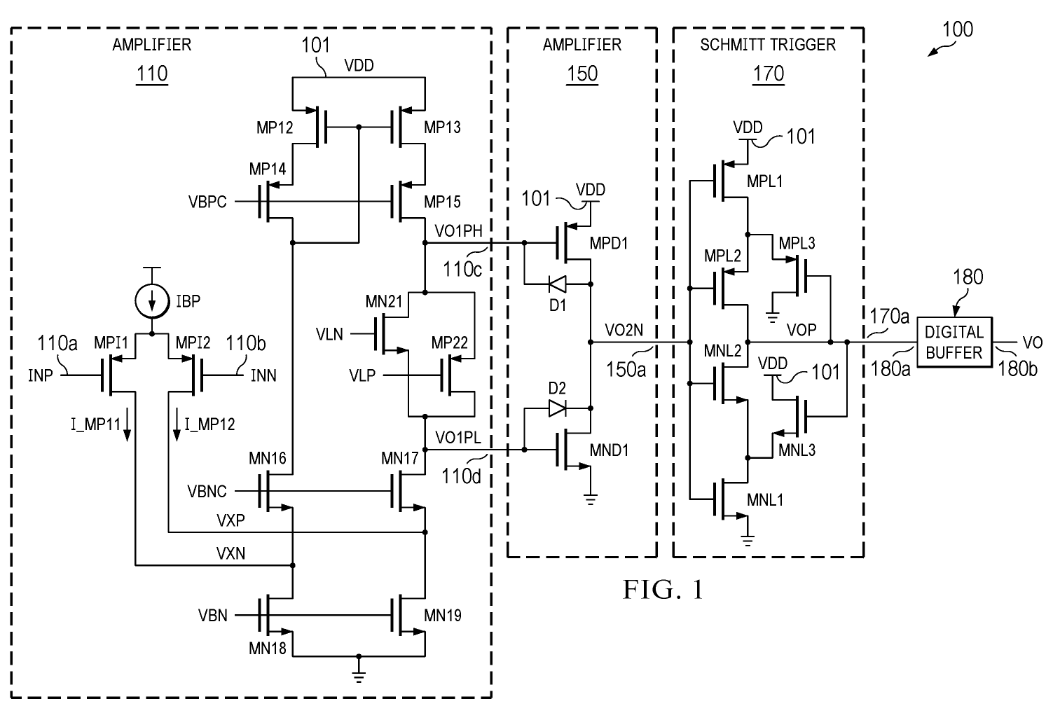

FIG. 1 is a schematic diagram of a comparator 100, in an example. Comparator 100 includes amplifiers 110 and 150, a Schmitt trigger 170, and a buffer 180. In the example of FIG. 1, amplifier 110 is a folded cascode amplifier, and amplifier 150 is a class AB amplifier. Comparator 100 has inputs 110a and 110b and outputs 180b, 180c, and 180d. Output 180c provides a voltage VSOP, which is proportional or equal to VO. Output 180d provides a voltage VSON which is a logical inverse of VO. The input signal to input 110a is INP, and the input signal to input 110b is INN. The output signal from comparator 100 is VO. In one example, comparator 100 asserts output signal VO to a logic high state in response to INP being greater than INN and asserts output signal VO to a logic low state in response to INP being smaller than INN.

Amplifier 110 includes a bias current source IBP and transistors MPI1, MPI2, MP12, MP13, MP14, MP15, MN21, MP22, MN16, MN17, MN18, and MN19. Transistors MPI1, MPI2, MP12, MP13, MP14, MP15, and MP22 are p-channel field effect transistors (PFETs), and transistors MN16, MN17, MN18, MN19, and MN21 are n-channel field effect transistors (NFETs). The gates of transistors MPI1 and MPIb are coupled to the comparator’s inputs 110a and 110b, respectively. Bias current source IBP is coupled to the sources of transistors MPI1 and MPI2 and provides bias current through those transistors. The drain of transistor MPI1 is coupled to the source of transistor MN16 and to the drain of transistor MN18. The drain of transistor MPI2 is coupled to the source of transistor MN17 and to the drain of transistor MN19. The sources of transistors MN18 and MN19 are coupled to ground. The gates of transistors MN16 and MN17 receive a bias voltage VBNC, and the gates of transistors MN18 and MN19 receive a bias voltage VBN.

The drains of transistors MN16 and MP14 are coupled together and to the gates of transistors MP12 and MP13. The source of transistor MP14 is coupled to the drain of transistor MP12. The sources of transistors MP12 and MP13 are coupled to a supply voltage terminal 101 and receive supply voltage VDD. The drain of transistor MP13 is coupled to the source of transistor MP15. The drains of transistors MP15 and MN21 and the source of MP22 are coupled together and to an output 110c of amplifier 110. The gates of transistors MN21 and MP22 receive bias voltages VLN and VLP, respectively. The source of transistor MN21 and the drain of transistor MP22 are coupled to the drain of transistor MN17 and to an output 110d of amplifier 110. The signals at outputs 110c and 110d of amplifier 110 are VO1PH and VO1PL, respectively.

As noted above, amplifier 110 in the example of FIG. 1 is a folded cascode amplifier. Bias current flows through the serial string of transistors MP12, MP14, MN16, and MN18 (referred to herein as the “lefthand branch” of amplifier 110). Similarly, bias current flows through the serial string of transistors MP13, MP15, MN17, and MN19 and through the transistor pair MN21 and MP22 (the “righthand branch”). Transistor pair MN21 and MP22 provide a direct current (DC)-level-shifted output (VO1PH, VO1PL) of amplifier 110. However, a difference in voltage between input signals INP and INN results in one of currents I_MP11 and I_MP12 being larger than the other. For example, if input signal INN is smaller than input signal INP, then current I_MP12 will be larger than current I_MP11. Conversely, if input signal INP is smaller than input signal INN, then current I_MP11 will be larger than current I_MP12. Current I_MP11 is injected into the drain of transistor MN18 and current I_MP12 is injected into the drain of transistor MN19.

Because of the fixed bias voltage VBN at the gates of transistors MN18 and MN19, the currents through transistors MN18 and MN19 are fixed. If current I_MP12 is larger than current I_MP11 (e.g., as a result of INP being larger than INN), the current through transistor MN17 will be smaller than the current through transistor MN16. The current through transistor MN16 flows through transistors MP12 and MP14 and is mirrored through transistor MP13 The larger current through transistor MN16 (compared to MN17) flows through transistor MP15 as well. Because the current from VDD through transistors MP13 and MP15 is larger than the current through transistors MN17 and MN19 to ground, both the outputs of the first amplifier (VO1PH, VO1PL) become higher than the DC bias voltages. By contrast, the outputs VO1PH and VO1PL decrease if current I_MP11 is larger than current I_MP12.

Amplifier 150 includes transistors MPD1 and MND1 and diodes D1 and D2. Transistor MPD1 is a PFET, and transistor MND1 is an NFET. The source of transistor MPD1 is coupled to the supply voltage terminal 101, and the source of transistor MND1 is coupled to ground. The drains of transistors MPD1 and MND1 are coupled together and to an output 150a of amplifier 150. The signal at the output 150a of amplifier 150 is signal VO2N. The anode of diode D1 is coupled to the drain of transistor MPD1, and the cathode of transistor D1 is coupled to the gate of transistor MPD1. The output 110c of amplifier 110 is coupled to the gate of transistor MPD1. The cathode of diode Ds is coupled to the drain of transistor MND1, and the anode of transistor D2 is coupled to the gate of transistor MND1. The output 110d of amplifier 110 is coupled to the gate of transistor MND1. Transistors MPD1 and MND1 operate in the linear region. Both of transistors MPD1 and MND1 generally remain on continuously during operation of comparator 100.

Schmitt trigger 170 includes transistors MPL1, MPL2, MPL3, MNL1, MNL2, and MNL3. Transistors MPL1, MPL2, and MPL3 are PFETs, and transistors MNL1, MNL2, and MNL3 are NFETs. Transistors MPL1 and MPL2 are coupled in series between the supply voltage terminal 101 and an output 170a of the Schmitt trigger. Transistors MNL2 and MNL1 are coupled in series between output 170a of and ground. The source of a transistor MPL3 is coupled to the drain of transistor MPL1 and to the source of transistor MPL2. The drain of transistor MPL3 is coupled to ground. The output 170a is coupled to the gates of transistor MPL3 and MNL3. The source of transistor MNL3 is coupled to the drain of transistor MNL1 and to the source of transistor MNL2. The drain of transistor MNL3 is coupled to the supply voltage terminal 101. The signal at the output 170a of Schmitt trigger 170 is signal VOP. Schmitt trigger 170 functions to signal VOP to either approximately VDD or ground based on the output signal VO2N is above or below a threshold of the Schmitt trigger.

The output 170a of Schmitt trigger 170 is coupled to an input 180a of buffer 180. An output of buffer 180 provides the output 180b of comparator 100. Buffer 180 may include voltage level shifting circuitry to shift the level of the output signal VOP from Schmitt trigger 170 to a level suitable for any circuitry connected to the output 180b of comparator 100.

Multiple problems can occur in comparator 100. First, comparator 100 may be designed to provide correct comparison functionality (comparing INP to INN)) as long as the inputs to the comparator do not violate the common mode voltage range for which proper operation of the comparator is ensured. The common mode voltage of a comparator is the switching point for the two input signals that cause the comparator’s output to change logic state. For example, if a reference voltage of 0.5V is provided to one input of a comparator, the comparator’s output will change logic state as the other input crosses 0.5V. A comparator is ensured to have proper operation as long as the common mode voltage if within a prescribed voltage range. The prescribed voltage range has a rated minimum value meaning that the common mode voltage should be above that level for proper operation of the comparator. Comparator 100 functions correctly as long as the common mode voltage is above a rated minimum of, for example, -0.2V. In one example, input 110b is coupled to a reference voltage, e.g., ground, and comparator 100 produces an output signal VO based on whether INP is above or below the reference voltage. It may be possible for signal INN to temporarily fall below ground. As long as INN remains above the lowest permitted common mode voltage (e.g., -0.2V), comparator 100 will continue to operate correctly. However, if signal INN temporarily falls below -0.2V, both transistors MPI1 and MPI2may operate inthe triode region instead of in the saturation region and may not produce a correct differential output current (I_MPI1-I_MPI2) to the drains of transistors MN18 and MN19. Accordingly, the output signal VO of comparator 100 may change polarity (a logic high becomes a logic low, or vice versa). The change in polarity of the output signal VO will be due to one input or the other of INP, INN falling below the rated minimum (e.g., -0.2V) and not because of a relative change in INP versus INN. Any circuitry connected to the output 180b of comparator 100 may then respond in an undesirable manner to a change in the logic polarity of output signal VO.

Second, as noted above transistor MPD1 and MND1 in the class AB amplifier 150 are continuously on (in their linear region). The source of transistor MND1 is coupled to ground. The drain of transistor MND1 has the voltage VO2N generated by amplifier 150. Accordingly, the drain-to-source voltage (Vds) of transistor MND1 is the voltage VO2N. With transistor MND1 on continuously, voltage VO2N may be larger enough to result in hot carrier injection (HCI) stress to transistor MND1. HCI stress may cause a reduction in drain current of transistor MND1 for the same gate-to-source voltage. The examples below address these problems.

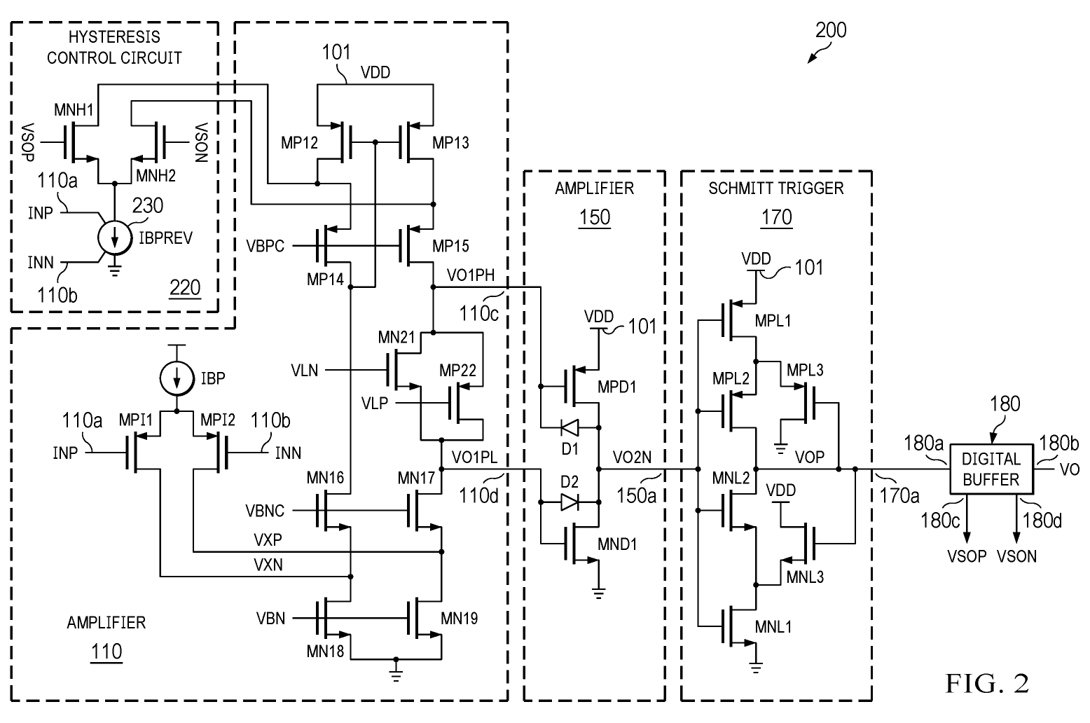

FIG. 2 is a schematic diagram of a comparator 200, in an example. Comparator 200 includes amplifiers 110 and 150, Schmitt trigger 170, and buffer 180 as described above, as well as a hysteresis control circuit 220. Descriptions of amplifiers 110 and 150, Schmitt trigger 170, and buffer 180 are provided above.

Hysteresis control circuit 220 includes transistors MNH1 and MNH2 (NFETs) coupled to a current source circuit 230. The sources of transistors MNH1 and MNH2 are coupled together and to current source circuit 230. The drain of transistor MNH1 is coupled to the drain of transistor MP12. The drain of transistor MNH2 is coupled to the drain of transistor MP13. The gate of transistor MNH1 receives voltage VSOP, and the gate of transistor MNH1 receives voltage VSON. Voltage VSOP is proportional to VO. For example, when VO is logic high, voltage VSOP also is logic high (e.g., at the same voltage as VO or a different voltage), and when VO is logic low, VSOP also is logic low. Voltage VSON is of the opposite logic polarity as VSOP. For example, when VSOP is logic high, VSON is logic low, and vice versa. Accordingly, one of transistors MNH1 and MNH2 will turn on depending on the logic polarity of VO. For example, if VO is logic high (and thus VSOP is logic high and VSON is logic low), transistor MNH1 (but not MNH2) will turn on, and if VO is logic low (and thus VSOP is logic low and VSON is logic high), transistor MNH2 (but not MNH1) will turn on.

Current source circuit 230 can be enabled and disabled. When current source circuit 230 is enabled, current IBPREV generated by current source circuit 230 flows through whichever of transistors MNH1 and MNH2 is on. When current source circuit 230 is disabled, no current flows through either of transistors MNH1 or MNH2. Current source circuit 230 has inputs coupled to inputs 110a and 110b of comparator 200. Current source circuit 230 is disabled when the common mode voltage of comparator is above its rated minimum. Current source circuit 230 is enabled when the common mode voltage of comparator is below the rated minimum.

When the current source circuit 230 is disabled (e.g., during normal operation of comparator 200 when the common mode voltage is above the rated minimum), no current flows through from either of transistor MP12 or MP13 through its respective transistor MNH1 and MNH2. Instead, all of the current through transistors MP12 and MP13 flows through transistors MP14 and MP15, respectively, and amplifier 110 operates as described above. In this state (current source circuit 230 disabled), hysteresis control circuit 220 does not add any hysteresis current to either the lefthand or righthand branches of amplifier 110. With current source circuit 230 disabled, the hysteresis voltage of amplifier 110, in the example of FIG. 2, is OV.

When the common mode voltage of comparator 200 falls below the rated minimum, current source circuit 230 becomes enabled. Based on whichever transistor MNH1 or MNH2 is on, current IBPREV generated by current source circuit 230 is synced from the corresponding lefthand or righthand branch of amplifier 110 to ground instead of flowing through the rest of amplifier 110. By syncing current from one branch or the other of amplifier 110, the output voltage levels of VO1PH and VO1PL are increased or decreased thereby preventing the output signal VO from changing logic state. For example, if VO is logic low when the comparator’s common mode voltage falls below the rated minimum, transistor MNH2 turns on and current source circuit 230 is enabled. In this state (MNH2 on and current source circuit 230 enabled), part of the current flowing through transistor MP13 (an amount of current equal to the current IBPREV) flows through transistor MNH2 instead of through transistor MP15. Hysteresis control circuit 220 is a current sink for the righthand branch of amplifier 110. The current through transistor MP15 decreases in response to transistor MNH2 turning on. Based on current through MP15 now being smaller than current through transistor MN17, the voltages of VO1PH and VO1PL decrease thereby reinforcing output signal VO at a logic low level.

By contrast, if VO is logic high when the comparator’s common mode voltage falls below the rated minimum, transistor MNH1 turns on and current source circuit 230 is enabled. Hysteresis control circuit 220 is a current sink for the lefthand branch of amplifier 110. In this state (MNH1 on and current source circuit 230 enabled), the current through transistor MP12 increases by an amount equal to current IBPREV. The current through transistor MP12 is mirrored through transistor MP13 and also flows through transistor MP15. As a result of an increase in current through transistor MP15 while the current through transistor MN17 remains unchanged, the voltages of VO1PH and VO1PL increase thereby reinforcing output signal VO at a logic high level.

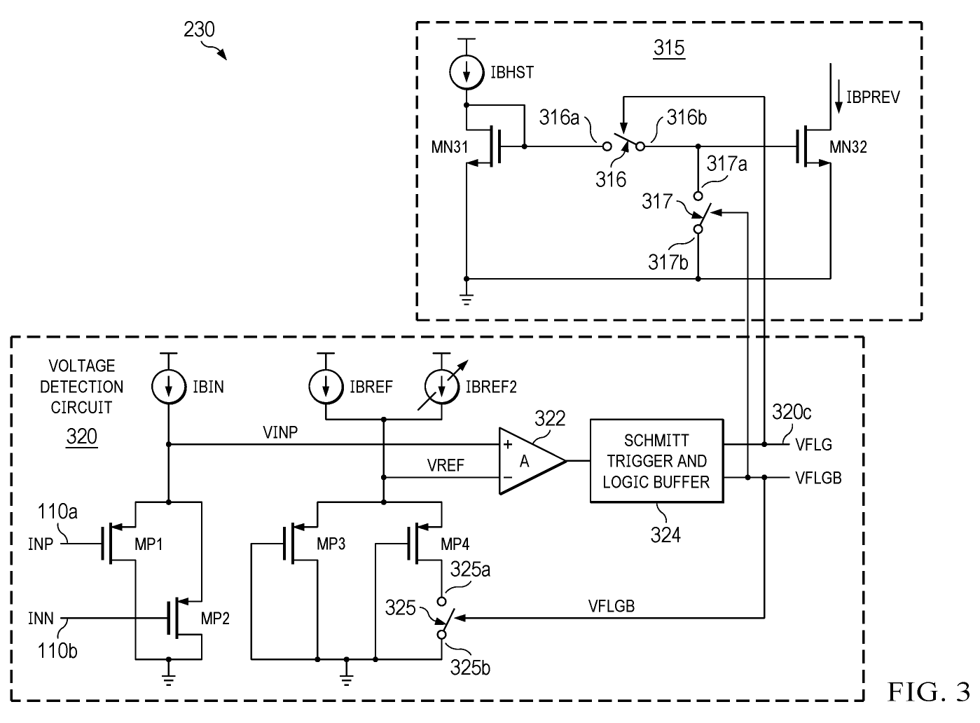

FIG. 3 is a schematic diagram of current source circuit 230, in an example. Current source circuit 230 includes a current mirror 315 coupled to a voltage detection circuit 320. Current mirror 315 includes transistors MN31 and MN32 (e.g., NFETs), switches 316 and 317, and current source circuit IBHST. The gate of transistor MN31 is coupled to terminal 316a of switch 316, the drain of transistor MN31, and to current source circuit IBHST. Terminal 316b of switch 316 is coupled to the gate of transistor MN32. Terminal 317a of switch 317 is coupled to the gate of transistor MN32, and terminal 317b is coupled to the sources of transistors MN31 and MN32 and to ground. In operation, either switch 316 is closed or switch 317 is closed. When switch 316 is closed (and switch 317 is open), transistors MN31 and MN32 are configured as a current mirror and the current from current source circuit IBHST is mirrored (e.g., a 1:1 mirror ratio) through transistor MN32 as current IBPREV, described above. When switch 316 is open and switch 317 is closed, current mirror 315 is disabled and current IBPREV does not flow through transistor MN32.

Voltage detection circuit 320 includes current source circuits IBIN, IBREF, and IPREF2, transistors MP1, MP2, MP3, and MP4 (PFETs), amplifier 322, Schmitt trigger and logic buffer 324, and switch 325. Current source circuits IBIN, IBREF, and IBREF2 produce a fixed amount of current. Current source circuit IBREF2 is trimmable. Current IBIN flows through one or the other or both of transistors MP1 and MP2 based on the relative voltage levels of signals INP and INN. Transistors MP1 and MP2 function as a source follower resulting in the voltage VINP at the sources of transistors MP1 and MP2 being -level-shifted by the threshold voltage of transistors MP1 and MP2 above the common mode voltage of comparator 200. The combined current from current sources IBREF and IBREF2 flows through transistors MP3 and MP4 (if switch 325 is closed), collectively resulting in a voltage VREF at the sources of transistors MP3 and MP4. If switch 325 is open, the combined current from current sources IBREF and IBREF2 flows through transistor MP3 but not transistor MP4 resulting in voltage VREF being larger than when switch 325 was closed. The open/closed state of switch 325 results in amplifier 322 and Schmitt trigger and logic buffer 324 having a sufficient hysteresis voltage to prevent the logic state of VFLG from changing state when VINP is approximately equal to VREF.

Amplifier 322 amplifies the difference between voltages VINP and VREF. The output voltage from amplifier 322 will be larger when VINP is higher than VREF and will be smaller when VINP is less than VREF. Schmitt trigger and logic buffer 324 may include an inverting Schmitt trigger. Accordingly, when VINP is larger than VREF, Schmitt trigger and logic buffer 324 converts the output voltage from amplifier 322 to a logic high for signal VFLG. Voltage detection circuit 320 includes an output 320c which provides signal VFLG. By contrast, when VINP is smaller than VREF, Schmitt trigger and logic buffer 324 converts the output voltage from amplifier 322 to a logic low for signal VFLG. Schmitt trigger and logic buffer 324 generates signal VFLGB at an opposite logic polarity as signal VFLG.

Signal VFLG is provided to a control terminal of switch 316, and signal VFLGB is provided to control terminals of switches 317 and 325. In one example, a logic high for signal VFLG and logic low for signal VFLGB results in switch 316 being closed and switches 317 and 325 to be open. A logic low for signal VFLG and logic high for signal VFLGB results in switch 316 being open and switches 317 and 325 being closed. Accordingly, when VINP is larger than VREF (normal operation, common mode voltage above the rated minimum), signal VFLG is logic low and signal VFLGB is logic high, and current mirror is disabled because VFLG is logic low. By contrast, when VINP is smaller than VREF (common mode voltage below the rated minimum), signal VFLG is logic high and signal VFLGB is logic low, and current mirror 315 is enabled thereby modifying the hysteresis voltage of amplifier 110 as described above.

Current source IBREF2 is trimmable such that signals VFLG and VFLGB are relatively insensitive to temperature variations. In one example, current source IBREF2 is implemented by summing together two currents having opposite temperature coefficients—one a positive to absolute temperature (PTAT) current and the other a complementary to absolute temperature (CTAT) current source. By adjusting the weights of the PTAT and CTAT currents (e.g., by adjusting the number of transistor fingers of transistors within each current source and thus the width-to-length (W/L) ratio), the temperature coefficient of current source IBREF2 can be adjusted.

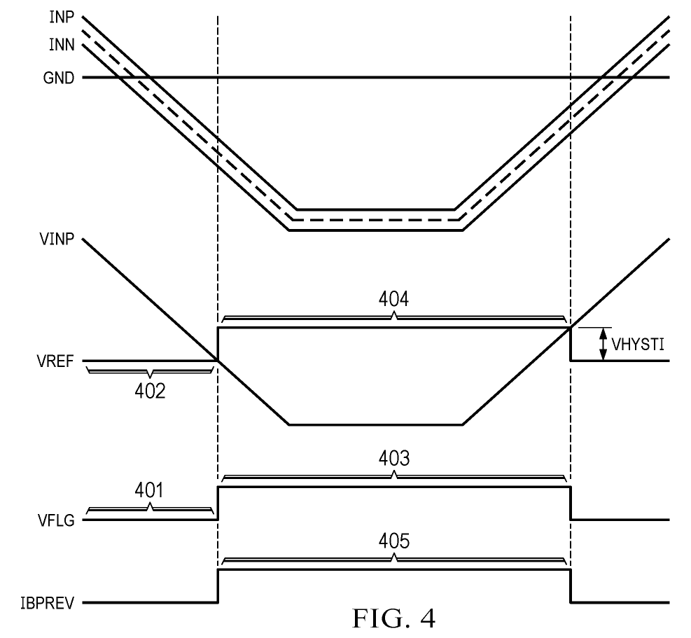

FIG. 4 are waveforms of signals INP, INN, VINP, VREF, and VFLG and current IBPREV further illustrating the operation of current source circuit 230. With signal VFLG at a logic low level at 401, switch 325 is closed causing VREF to be at a lower level 402, switch 316 is open, and switch 317 is closed thereby disabling current mirror 315. As the common mode voltage VINP of comparator 200 falls, eventually, VINP will be below VREF, and as a result, Schmitt trigger and logic buffer 324 forces signal VFLG to a logic high level at 403. With VFLG logic high and VFLGB logic low, switch 316 closes and switches 317 and 325 open. Opening switch 325 results in VREF increasing to a higher level at 404, thereby implementing a hysteresis voltage VHYSTI for amplifier 322 and Schmitt trigger and logic buffer 324. Closing switch 316 and opening switch 317 results in current mirror 315 being enabled. With current mirror 315 enabled, current IPREV increases to a higher level at 405 thereby sinking current from either the lefthand or righthand branches of amplifier 110 depending on the present logic state of VO, as described above.

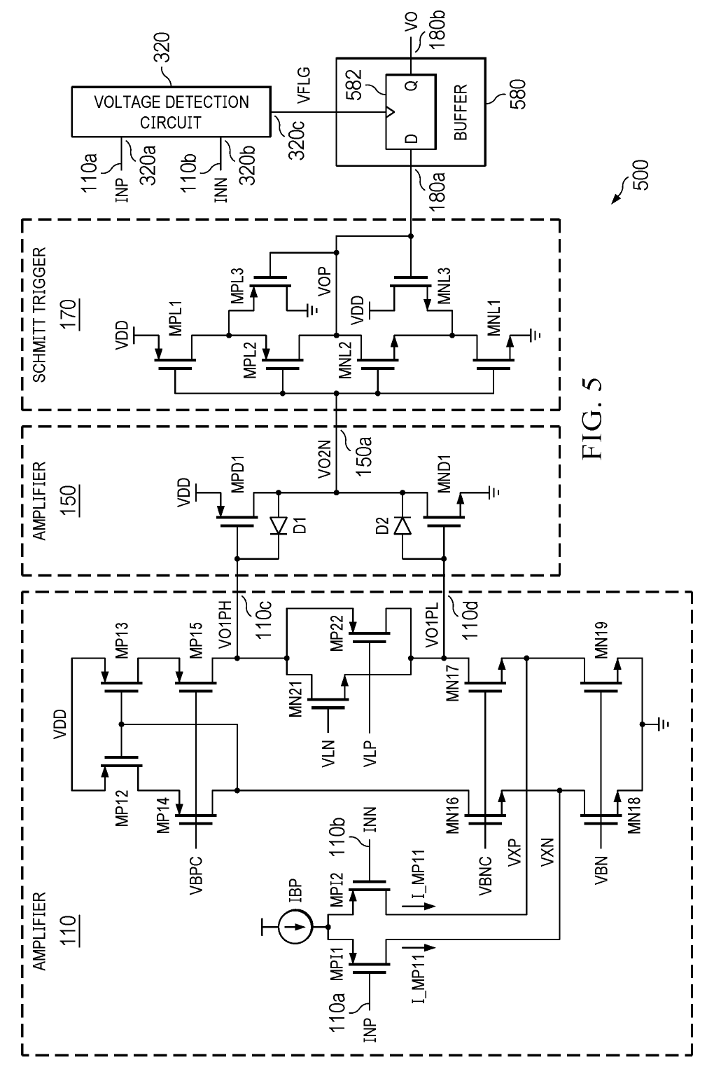

FIG. 5 is a schematic diagram of a comparator 500, in an example. Comparator 200 includes amplifiers 110 and 150, Schmitt trigger 170, and the voltage detection circuit 320, as described above, as well as a buffer 580. Buffer 580 may include voltage level shifting circuitry and a latch 582. In one example, latch 582 is a transparent latch having a clock input, a data (D) input, and a Q output. The Q output of a transparent latch follows the input D until a pulse occurs at the clock input, at which the logic state of the signal at the D input is latched as the Q output. The signal to the D input of latch 582 is the output signal VOP from Schmitt trigger 170, and the signal from the Q output of latch 582 is signal VO.

The output 320c of voltage detection circuit 320 is coupled to the clock input of latch 582. When VFLG is logic low (normal operation in which the comparator’s common mode voltage exceeds the rated minimum), the VO signal from the Q output of latch 582 follows signal VOP, that is when VOP is logic low, VO also is logic low, and when VOP is logic high, VO also is logic high. When VIP falls below VREF (FIG. 3), voltage detection circuit 320 forces signal VFLG to a logic high state. A rising edge of signal VFLG results in latch 582 latching the logic state of signal VOP as output signal VO. For example, if VOP is logic high when VIP falls below VREF, latch 582 latches signal VO at a logic high state. By contrast, if VOP is logic low when VIP falls below VREF, latch 582 latches signal VO at a logic low state. By latching the logic state of the output signal VOP from Schmitt trigger 170 as signal VO of the comparator, output signal VO will not change logic state while the common mode voltage of comparator 500 is below the rated minimum.

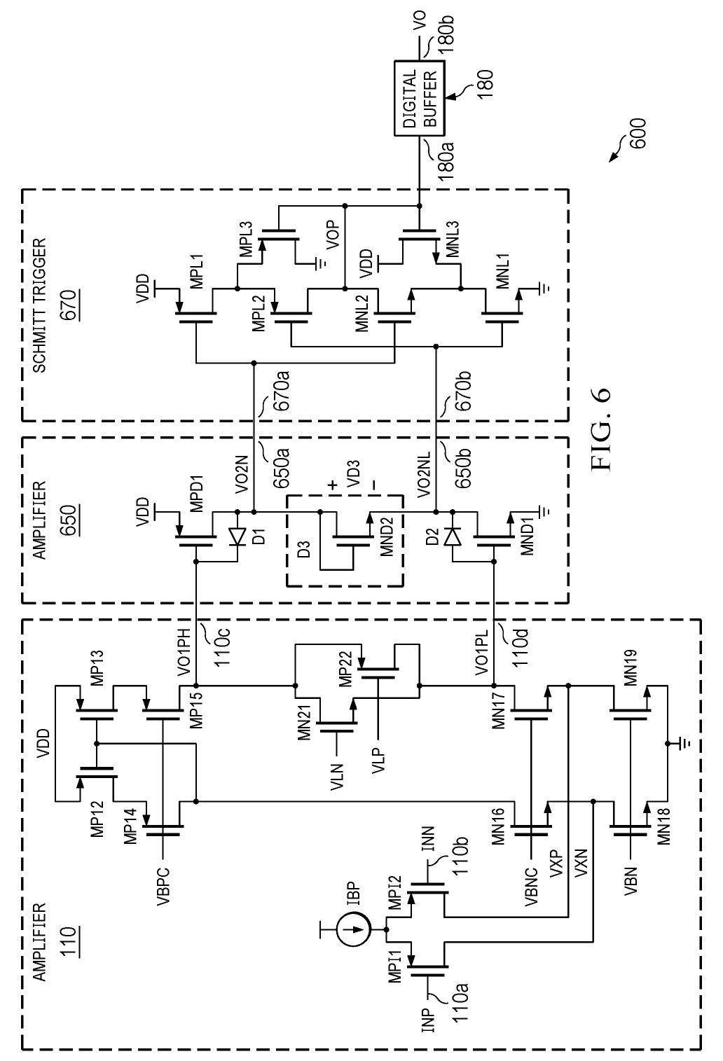

FIG. 6 is a schematic diagram of a comparator 600, in an example. Comparator 600 includes amplifiers 110 and 650, a Schmitt trigger 770, and a buffer 180. Amplifier 110 may be a folded cascode amplifier as described above. Amplifier 650 is a class AB amplifier that includes transistors MPD1 and MPD2 and diodes D1 and D2 (described above) and a diode device D3. In the example of FIG. 6, diode device D3 includes a diode-connected transistor MND2 (e.g., an NFET), in which the drain is connected to the gate. The drain of diode-connected transistor MND2 is coupled to the drain of transistor MPD1, and the source of diode-connected transistor MND2 is coupled to the drain of transistor MND1. In another example, diode device D3 is a diode.

The voltage drop across diode device D3 is VD3. The voltage drop VD3 across diode device D3 for comparator 600 in FIG. 6 results in a smaller Vds across transistor MND1 than would be the case across transistor MND1 for comparator 100 in FIG. 1. Because transistor MND1 in FIG. 6 has a smaller Vds than for transistor MND1 in FIG. 1, the HCI stress caused to transistor MND1 in comparator 600 advantageously is reduced if not eliminated.

Amplifier 650 has two outputs, 650a (which has voltage VO2N) and 650b (which has voltage VO2NL) instead of a single output 150a as in FIG. 1. The outputs 650a and 650b are taken from the drain and source, respectively, of diode-connected transistor MND2. Because amplifier 650 has two outputs, Schmitt trigger 670 is a two-input Schmitt trigger—inputs 670a and 670b. Input 670a of Schmitt trigger 670 is coupled to output 650a, and input 670b is coupled to output 650b. Schmitt trigger 670 is similar to Schmitt trigger 170 in FIGS. 1, 2, and 5 but the gates of transistors MPL1 and MNL2 are coupled through input 670a to output 650a of amplifier 650, and the gates of transistors MPL2 and MNL1 are coupled through input 670b to output 650b of amplifier 650.

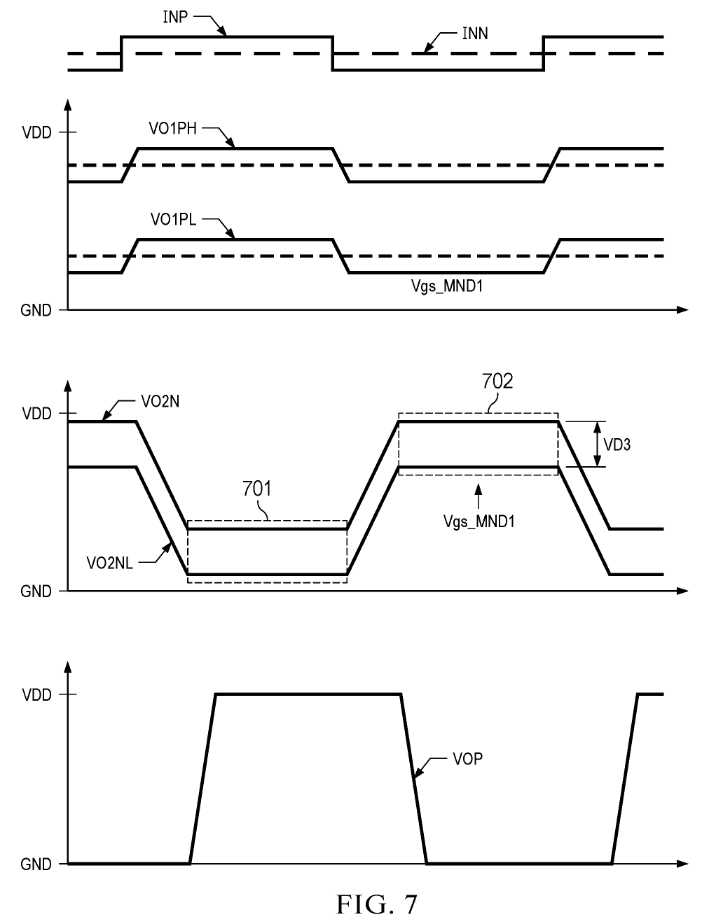

FIG. 7 are waveforms illustrating the operation and benefit of the inclusion of diode device D3 in amplifier 650. FIG. 7 has example waveforms for input signals INN and INP, voltages VO1PH, VO1PL, VO2N, VO2NL, and VOP, and output signal VO. When input signal INP is greater than INN, voltages VO2N and VO2NL are at a lower level 701, and when input signal INP is smaller than INN, voltages VO2N and VO2NL are at a higher level 702. However, the voltage drop VD3 between the drains of transistors MPD1 and MND1 caused by diode device D3 results in voltage VO2NL remaining voltage VD3 below voltage VO2N. By contrast, the voltage VO2N in FIG. 1 can range from near ground to near VDD. Voltage VO2NL in FIG. 6 and voltage VO2N in FIG. 1 represent the Vds of transistor MND1 in the respective comparators. In FIG. 1, the Vds of transistor MND1 can be as high as approximately VDD. Advantageously, in FIG. 6 the Vds of transistor MND1 can be as high as only VDD minus VD3, thereby reducing the effects of any HCI stress to transistor MND1.

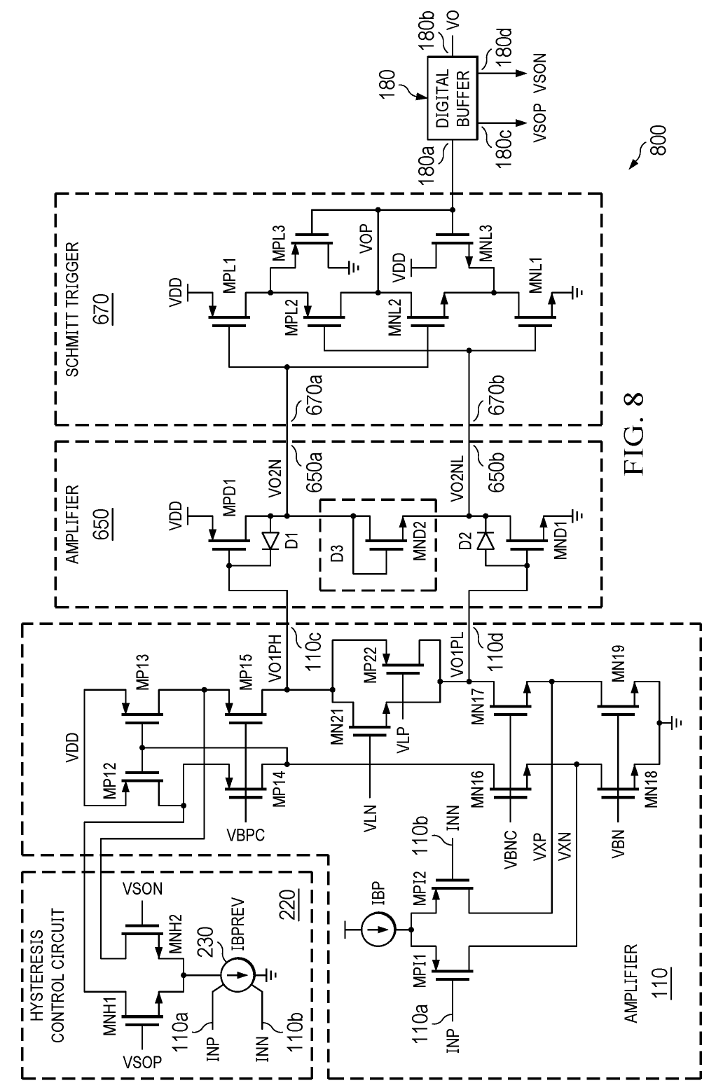

FIG. 8 is a schematic diagram of a comparator 800 that combines both hysteresis control circuit 220 coupled to amplifier 110 and diode device D3 included with amplifier 650. Comparator 800 includes Schmitt trigger 670 and buffer 180. The circuits shown in FIG. 8 are described above. By including both hysteresis control circuit 220 and diode device D3, comparator 800 advantageously avoids logic state reversals of output signal VO when the comparator’s common mode voltage is below the rated minimum and reduces or eliminates the HCI stress on transistor MND1.

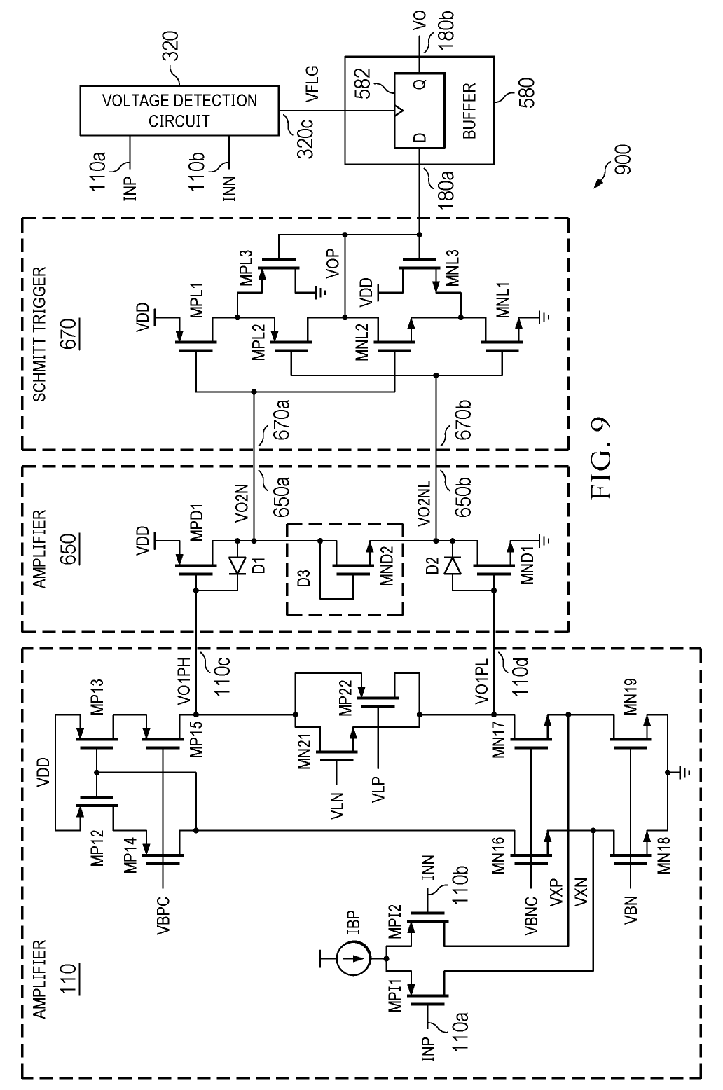

FIG. 9 is a schematic diagram of a comparator 900 that combines both voltage detection circuit 320 coupled to latch 582 within buffer 580 and diode device D3 included with amplifier 650. Comparator 900 includes Schmitt trigger 670 and buffer 580. The circuits shown in FIG. 9 are described above. By including both latch 582 clocked by signal VFLG from voltage detection circuit 320 and diode device D3 within amplifier 650, comparator 900 advantageously avoids logic state reversals of output signal VO when the comparator’s common mode voltage is below the rated minimum and reduces or eliminates the HCI stress on transistor MND1.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor’s control input and its current terminals. In the context of a FET, the control input is the gate, and the current terminals are the drain and source. In the context of a BJT, the control input is the base, and the current terminals are the collector and emitter. The gate, source, and drain of a FET and base, collector, and emitter of a BJT are terminals of the transistor.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor’s body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

Modifications are possible in the described examples, and other examples are possible, within the scope of the claims.

What is claimed is:

1. An apparatus, comprising:
a first amplifier having first and second inputs and first and second outputs;
a first transistor having first and second terminals, the first terminal coupled to a third terminal of the first amplifier;
a second transistor having fourth and fifth terminals, the fourth terminal coupled to a sixth terminal of the first amplifier, and the fifth and second terminals coupled together;
a current source circuit having a first input coupled to the first input of the first amplifier, a second input coupled to the second input of the first amplifier, and having a current source circuit terminal coupled to the second and fifth terminals;
a second amplifier having a first input coupled to the first output of the first amplifier, having a second input coupled to the second output of the first amplifier, and having first and second outputs, the second amplifier including a third transistor having a first control terminal coupled to the first output of the first amplifier, a fourth transistor having a second control terminal coupled to the second output of the first amplifier, and a diode device coupled between the third and fourth transistor; and
a Schmitt trigger having a first input coupled to the first output of the second amplifier and having a second input coupled to the second output of the second amplifier.

2. The apparatus of claim 1, wherein the first amplifier includes a folded cascode amplifier.

3. The apparatus of claim 1, wherein a combination of the first and second transistors and the current source circuit is configured to change an output voltage of the first amplifier in response to a common mode voltage at the first and second inputs of the first amplifier being below a threshold.

4. The apparatus of claim 1, wherein the current source circuit includes:
a current mirror having a control input; and
a voltage detection circuit having a control output coupled to the control input of the current mirror, the voltage detection circuit configured to disable the current mirror in response to a common mode voltage at the first and second inputs of the first amplifier being above a threshold and to enable the current mirror in response to the common mode voltage being below the threshold.

5. The apparatus of claim 4, wherein the current mirror includes:
a fifth transistor;
a sixth transistor; and
a switch coupled between the fifth and sixth transistors, the switch having a control terminal coupled to the control input of the current mirror.

6. The apparatus of claim 4, wherein the Schmitt trigger has an output and wherein one or the other of the first and second transistors are configured to be on based on an output of the Schmitt trigger.

7. The apparatus of claim 1, wherein the diode device includes a diode-connected transistor.

8. The apparatus of claim 1, wherein the second amplifier includes a class AB amplifier.

9. The apparatus of claim 1, wherein the apparatus is a comparator.

10. An apparatus, comprising:
a first amplifier having first and second inputs and first and second outputs;
a second amplifier having a first input coupled to the first output of the first amplifier, a second input coupled to the second output of the first amplifier, and having first and second outputs, the second amplifier including a first transistor having a first control terminal coupled to the first output of the first amplifier, a second transistor having a second control terminal coupled to the second output of the first amplifier, and a diode device coupled between the first and second transistor;
a Schmitt trigger having a first input coupled to the first output of the second amplifier, having a second input coupled to the second output of the second amplifier, and having an output; a
a voltage detection circuit having a first input coupled to the first input of the first amplifier, a second input coupled to the second input of the second amplifier, and having an output, the voltage detection circuit configured to generate a signal at the output of the voltage detection circuit based on whether a common mode voltage at the first and second inputs of the first amplifier is below or above a threshold; and
a latch coupled to the output of the Schmitt trigger and to the output of the voltage detection circuit, the latch configured to latch the output of the Schmitt trigger in response to the signal from the voltage detection circuit indicating that the common mode voltage is below the threshold.

11. The apparatus of claim 10, wherein the latch is a transparent latch having a clock input coupled to the output of the voltage detection circuit.

12. An apparatus, comprising:
an amplifier having first and second inputs and an output; and
a hysteresis control circuit having a first input coupled to the first input of the amplifier, having a second input coupled to the second input of the amplifier, and having first and second outputs coupled to the amplifier, the hysteresis control circuit configured to be disabled in response to a common mode voltage at the first and second inputs of the amplifier being above a threshold and to be enabled in response to the common mode voltage being below the threshold, and when enabled the hysteresis control circuit is configured to change an output voltage of the amplifier.

13. The apparatus of claim 12, further comprising a buffer having an input coupled to the output of the amplifier.

14. The apparatus of claim 12, wherein the hysteresis control circuit includes:
a current mirror having a control input; and
a voltage detection circuit having a control output coupled to the control input of the current mirror, the voltage detection circuit configured to disable the current mirror in response to the common mode voltage being above the threshold and to enable the current mirror in response to the common mode voltage being below the threshold.

15. The apparatus of claim 14, wherein the current mirror includes:
a first transistor;
a second transistor; and
a switch coupled between the first and second transistors, the switch having a control terminal coupled to the control input of the current mirror.

16. The apparatus of claim 14, wherein the current mirror has a current mirror output, and wherein the hysteresis control circuit includes:
a first transistor having a first control terminal a transistor terminal, the first control terminal coupled to the first input of the hysteresis control circuit; and
a second transistor having a second control terminal and a transistor terminal, the second control terminal coupled to the second input of the hysteresis control circuit, and the transistor terminals of the first and second transistors coupled together and to the current mirror output.

17. The apparatus of claim 12, wherein the amplifier includes a folded cascode amplifier coupled to a class AB amplifier.

18. An apparatus, comprising:
a first amplifier having first and second inputs and first and second outputs;
a second amplifier having a first input coupled to the first output of the first amplifier, a second input coupled to the second output of the first amplifier, and having first and second outputs, the second amplifier including a first transistor having a first control terminal coupled to the first output of the first amplifier, a second transistor having a second control terminal coupled to the second output of the first amplifier, and a diode device coupled between the first and second transistor; and
a Schmitt trigger having a first input coupled to the first output of the second amplifier and having a second input coupled to the second output of the second amplifier.

19. The apparatus of claim 18, wherein the second amplifier is a class AB amplifier.

20. The apparatus of claim 18, wherein the diode device is a diode-connected transistor.
